(19) United States
(12) Patent Application Publication
(10) Pub. No.: US 2025/0125148 A1
(43) Pub. Date: Apr. 17, 2025

(54) METHOD FOR TWO-DIMENSIONAL MENTAL LINE PATTERNING

(71) Applicant: TAIWAN SEMICONDUCTOR MANUFACTURING COMPANY, LTD., Hsinchu (TW)

(72) Inventors: Chia-Chen LEE, Hsinchu (TW); Chia-Tien WU, Hsinchu (TW); Wei-Chen CHU, Hsinchu (TW); Hsi-Wen TIEN, Hsinchu (TW); Wei-Cheng TZENG, Hsinchu (TW); Ching-Yu HUANG, Hsinchu (TW); Wei-Cheng LIN, Hsinchu (TW); Ken-Hsien HSIEH, Hsinchu (TW)

(73) Assignee: TAIWAN SEMICONDUCTOR MANUFACTURING COMPANY, LTD., Hsinchu (TW)

(21) Appl. No.: 18/486,203

(22) Filed: Oct. 13, 2023

(51) Int. Cl. H01L 21/033; H01L 21/311; H01L 21/768

(52) U.S. Cl. CPC H01L 21/0337; H01L 21/31144; H01L 21/76877

(57) ABSTRACT

A method of semiconductor fabrication includes forming a plurality of mandrel recesses in a mandrel layer over a hard mask layer, performing a first patterning process on a spacer layer that is deposited over the mandrel layer to form a first opening pattern, performing a second patterning process to etch portions of the mandrel layer to form a second opening pattern, performing a third patterning process to form a third opening pattern in the hard mask layer based on the first opening pattern and the second opening pattern, and forming, through the hard mask layer, metal lines that are in a semiconductor layer under the hard mask layer and that are arranged in a pattern which corresponds to the third opening pattern.

### BACKGROUND

With the development of semiconductor technology and industry, dimensions of components, such as transistors and metal lines, in integrated circuits (ICs) are reduced to improve the power and speed performance of the ICs. Photolithography is one of various processing techniques adapted to scale down the components and spacings between the components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a two-dimensional (2D) metal line pattern in accordance with some embodiments.

FIG. 2 is a flow chart that illustrates steps of a method for 2D patterning in accordance with some embodiments.

FIGS. 3A, 3B, 4A, 4B, 5A, 5B, 6A, 6B, 7A, 7B, 8A, 8B, 9A, 9B, 10A, 10B, 10C, 11A, 11B, 11C, 12A, 12B, 13A, 13B, 14A, 14B, 15A and 15B are sectional views and top views of intermediate stages of the method of FIG. 2 in accordance with some embodiments.

FIG. 16 is a flow chart that illustrates steps of a method for 2D patterning in accordance with some embodiments.

FIGS. 17A, 17B, 18A and 18B are sectional views and top views of some intermediate stages of the method of FIG. 16 in accordance with some embodiments.

FIG. 19 is a schematic diagram illustrating metal lines that are formed using a method for 2D patterning in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “top,” “bottom,” “under,” “adjacent,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

In an example of a one-dimensional (1D) metal line pattern, each of multiple metal lines included in the 1D metal line pattern extends in one direction and has a uniform line width while a minimum pitch is smaller than 70 nanometers (nm). It is noted that the minimum pitch is a sum of a minimum line width (i.e., the critical dimension, CD) of one of the metal lines and a minimum spacing distance between two adjacent ones of the metal lines. This example of 1D metal line pattern may be achieved by performing a multiple patterning process and by using photolithography equipment.

In the development of patterning technology, design flexibility is restricted due to dimension shrinkage and photolithography limitations. Two-dimensional (2D) photolithography for forming a metal line having a non-uniform line width is difficult to achieve while having the minimum pitch smaller than 70 nm. In the present disclosure, a self-aligned 2D patterning is proposed, which can simultaneously realize the non-uniform line width and extremely small minimum pitch.

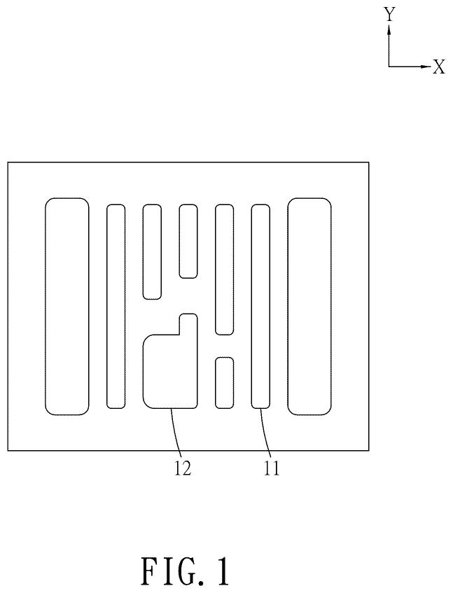

FIG. 1 is a schematic diagram illustrating a 2D metal line pattern formed on a semiconductor substrate (not shown) using a self-aligned 2D patterning technique in accordance with some embodiments. The 2D metal line pattern includes metal lines that are arranged and spaced apart from each other in a transverse direction (e.g., an X-axis direction as shown in FIG. 1) and that extend in a longitudinal direction (e.g., a Y-axis direction as shown in FIG. 1). The 2D metal line pattern is formed with a minimum pitch of smaller than 70 nm as with the example of the 1D metal line pattern, wherein the minimum pitch is a sum of a minimum line width and a minimum spacing distance. The metal lines of the 2D metal line pattern may be divided into a first metal line group that includes metal lines in the odd-numbered columns (e.g., the first, third, fifth and seventh columns) from the left as exemplarily shown in FIG. 1 and a second metal line group that includes metal lines in the even-numbered columns (e.g., the second, fourth and sixth columns) from the left of FIG. 1. The metal lines include at least one on-rule line 11 that has a uniform width equaling the minimum line width. The name “on-rule” line indicates that this line is formed using photolithography equipment (e.g., a photolithography exposure tool) following a target design rule of a photolithography technique to achieve the minimum line width in a multiple patterning process. Moreover, at least one of the metal lines has a non-uniform line width, that is to say, having metal line segments with different line widths (i.e., with different dimensions in the X-axis direction as shown in FIG. 1), hence reflecting the name “2D” and being referred to as an irregular-width line 12 hereinafter. The non-uniform line width is not smaller than the minimum line width. The irregular-width line 12 may be spaced apart from an adjacent one of the metal lines by the minimum spacing distance as can be achieved in the example of the 1D metal line pattern by performing the multiple patterning process using photolithography equipment. In some embodiments, the irregular-width line 12 has a length greater than 20 nm. It is noted that the on-rule line 11 may belong to any one of the first metal line group and the second metal line group as long as its width is equal to the minimum line width, and the irregular-width line 12 may encompass adjacent metal lines in the first metal line group and the second metal line group. In the illustrative embodiment, the irregular-width line 12 encompasses a metal line in the third column from the left of FIG. 1 and a metal line in the fourth column from the left of FIG. 1.

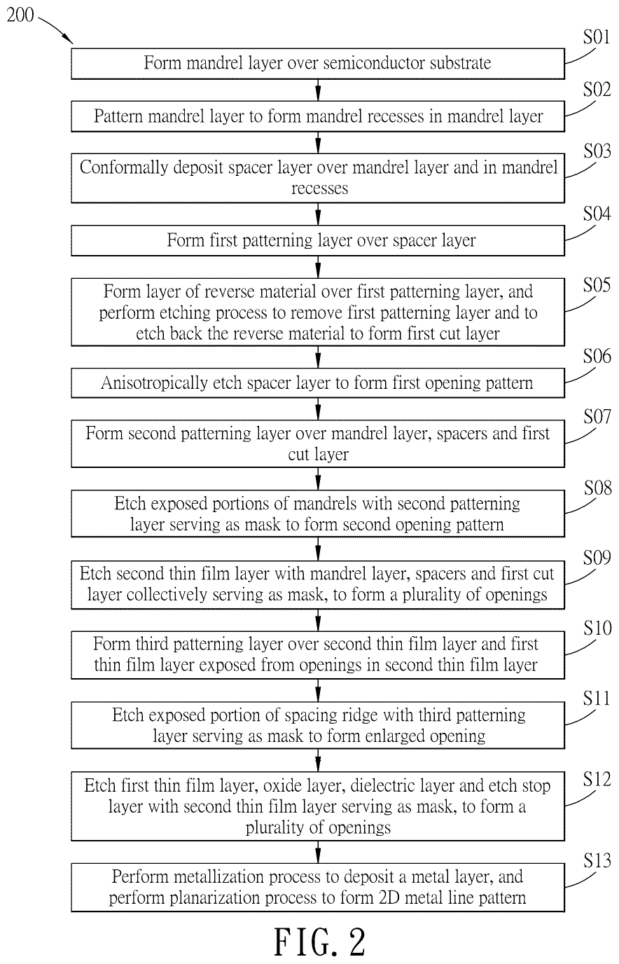

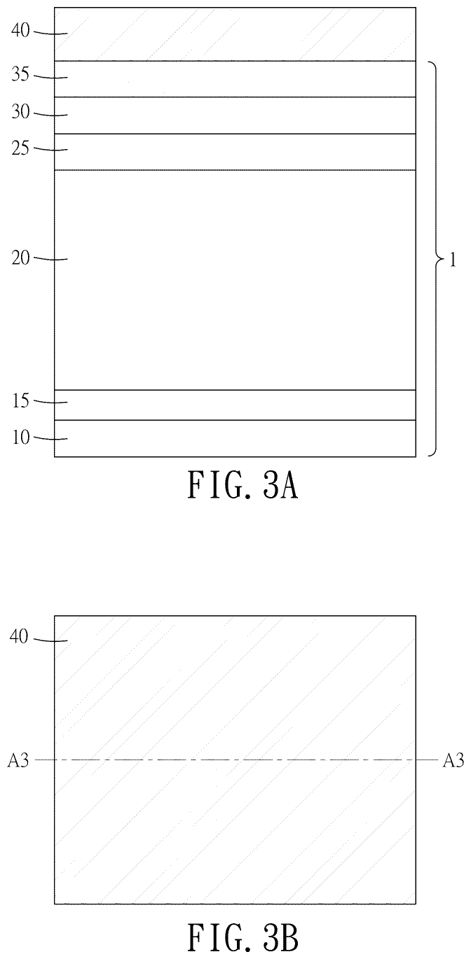

FIG. 2 is a flow diagram illustrating a method 200 for 2D patterning utilized to fabricate the 2D metal line pattern as exemplarily shown in FIG. 1 in accordance with some embodiments. FIGS. 3A, 3B, 4A, 4B, 5A, 5B, 6A, 6B, 7A, 7B, 8A, 8B, 9A, 9B, 10A, 10B, 10C, 11A, 11B, 11C, 12A, 12B, 13A, 13B, 14A, 14B, 15A and 15B illustrate schematic sectional views of some intermediate stages of the method 200 in accordance with some embodiments. Some portions may be omitted in the aforementioned figures for the sake of brevity. Additional steps can be provided before, after or during the method 200, and some of the steps described herein may be replaced by other steps or be eliminated. Similarly, further additional features may be present in the semiconductor device, and/or features present may be replaced or eliminated in additional embodiments.

Referring to FIG. 2 and the example illustrated in FIGS. 3A and 3B, the method 200 begins at step S01, where a mandrel layer 40 is formed over a semiconductor substrate 1. where FIG. 3B is a top view of a structure at this stage, and FIG. 3A depicts a sectional view taken along line A3-A3 in FIG. 3B. In the illustrative embodiment, the semiconductor substrate 1 includes a semiconductor device layer 10, an etch stop layer 15 formed over the semiconductor device layer 10, a dielectric layer 20 formed over the etch stop layer 15, an oxide layer 25 formed over the dielectric layer 20, a first thin film layer 30 formed over the oxide layer 25, and a second thin film layer 35 formed over the first thin film layer 30, wherein the first thin film layer 30 and the second thin film layer 35 cooperatively form a masking layer that is used to pattern the oxide layer 25, the dielectric layer 20 and the etch stop layer 15.

The semiconductor device layer 10 may include a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor device layer 10 may be made of a suitable semiconductor material, such as silicon or the like. In some embodiments, the semiconductor device layer 10 is a silicon substrate; and in other embodiments, the semiconductor device layer 10 is made of a compound semiconductor such as silicon carbide, gallium arsenide, indium arsenide, indium phosphide or other suitable materials. In still other embodiments, the semiconductor device layer 10 is made of an alloy semiconductor such as GaAsP, AlInAs, AlGaAs, GaInAs, GaInP, GaInAsP or other suitable materials.

In some embodiments, the semiconductor device layer 10 may include various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the semiconductor device layer 10 may include other functional elements such as resistors, capacitors, diodes, transistors, and/or the like. The transistors are, for example but not limited to, field effect transistors (FETs), such as planar FETs and/or 3D FETs (e.g., FinFETs, GAAFETs). The semiconductor device layer 10 may include lateral isolation features (e.g., shallow trench isolation (STI)) configured to separate various functional elements formed on the semiconductor device layer 10 and/or various functional elements formed in the semiconductor device layer 10. The semiconductor device layer 10 may include conductor lines that interconnect the aforesaid functional elements.

The etch stop layer 15 is of a single-layer structure or a multi-layer structure depending on etch stopping requirements, and includes, for example but not limited to, SiCN, SiO₂, SiNₓ, AlOₓN_{y}, metal oxide (represented as MOₓ, where M can be, for example, Ru, W, Ta, Ti, Al, Co, or other suitable metal elements), other suitable materials, or any combination thereof.

The dielectric layer 20 includes, for example but not limited to, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., AlOₓ, AlOₓN_{y}, AlOₓC_{y}, or other suitable compositions), an oxygen-doped carbide (ODC), a nitrogen-doped carbide (NDC), a tetraeythlorthosilicate (TEOS) oxide, a plasma enhanced oxide (PEOX), other suitable materials, or any combination thereof.

The oxide layer 25 is of a single-layer structure or a multi-layer structure depending on requirements, and includes, for example but not limited to, silicon containing oxide (e.g., Siₓ₁Oₓ₂, Siₓ₁Oₓ₂Cₓ₃, Siₓ₁Oₓ₂Cₓ₃Nₓ₄, or other suitable compositions), metal oxide (e.g., AlOₓ, AlOₓN_{y}, AlOₓC_{y}, or other suitable compositions), other suitable materials, or any combination thereof.

The first thin film layer 30 is a metal layer, and includes, for example but not limited to, W, Ti, Ta, Ru, Mo, Nb, other suitable materials, or any combination thereof. In some embodiments, aside from one or more metal elements, the first thin film layer 30 may further include, N, C, O, H, other suitable materials, or any combination thereof.

The second thin film layer 35 is an oxide layer, and includes, for example but not limited to, SiO₂, metal oxide (MOₓ, where M can be, for example, W, Ru, Mo, Ti, Ta, Nb, Sn, Al, or other suitable metal elements), other suitable materials, or any combination thereof. The first thin film layer 30 and the second thin film layer 35 may each be formed into a single-layer structure or a multi-layer structure depending on its function, such as serving as an etching stop or a patterning mask. In the illustrative embodiment, the first thin film layer 30 may be used as an etch stop layer during etching of the second thin film layer 35, and the second thin film layer 35 may be used as a hard mask layer for patterning the dielectric layer 20. In accordance with some embodiments, each of the first thin film layer 30 and the second thin film layer 35 may have a thickness in a range from about 50 angstroms to about 500 angstroms.

The mandrel layer 40 is of a single-layer structure or a multi-layer structure, and includes one or more elements of, for example but not limited to, Si, O, C, N, H, W, Ru, Mo, Ti, Ta, Nb, Sn, Al, etc. In some embodiments, the mandrel layer 40 may include SiCN, SiO₂, SiNₓ, AlOₓN_{y}, metal oxide (MOₓ, where M can be, for example, W, Ru, Mo, Ti, Ta, Nb, Sn, Al, or other suitable metal elements), other suitable materials, or any combination thereof. The mandrel layer 40 is formed using, for example but not limited to, physical vapor deposition (PVD), chemical vapor deposition (CVD), atomic layer deposition (ALD), other suitable techniques, or any combination thereof, and has a thickness in a range from about 50 angstroms to about 500 angstroms in accordance with some embodiments.

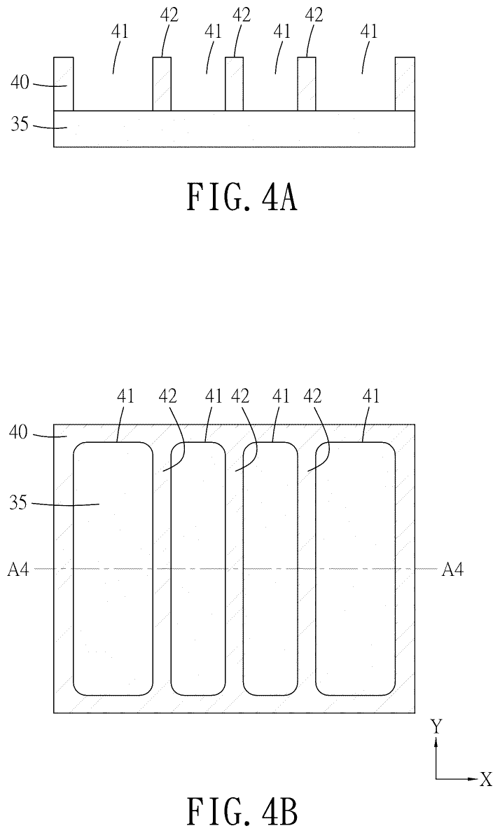

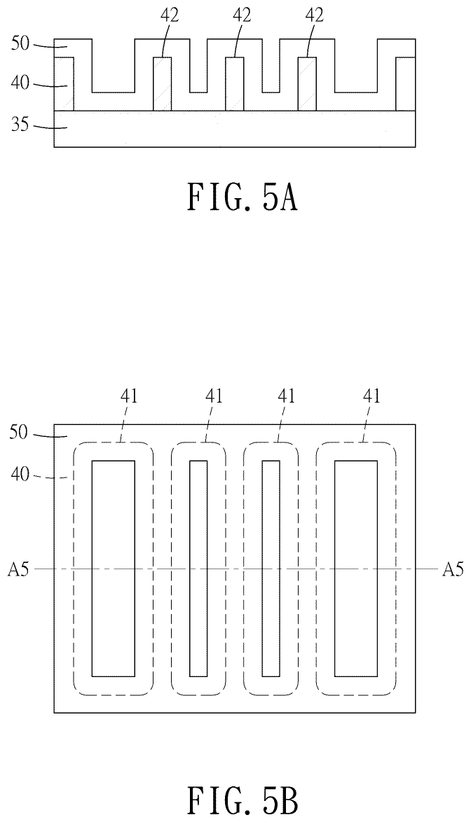

Referring to FIG. 2 and the example illustrated in FIGS. 4A and 4B, the method 200 proceeds to step S02, where the mandrel layer 40 is patterned through, for example, a photolithography process, an etching process and/or a trimming process, to form in the mandrel layer 40 a plurality of mandrel recesses (or called openings) 41 that expose the second thin film layer 35. The etching process may include, for example, wet etching, dry etching, other suitable techniques, or any combination thereof. FIG. 4B is a top view of a structure at this stage, and FIG. 4A depicts a sectional view taken along line A4-A4 in FIG. 4B. It is noted that FIG. 4A omits the layers 10, 15, 20, 25, and 30 for the sake of clarity, and so do FIGS. 5A, 6A, 7A, 8A, 9A, 10A and 10B. The mandrel recesses 41 are arranged and spaced apart from each other in the X-axis direction, extend in the Y-axis direction, and form a plurality of mandrels 42 in the mandrel layer 40, where the mandrels 42 are arranged and spaced apart from each other in the X-axis direction and extend in the Y-axis direction. Each of the mandrels 42 is a portion of the mandrel layer 40 that is disposed between adjacent two of the mandrel recesses 41. The widths of the mandrel recesses 41 (i.e., the width of the mandrel openings) are related to line widths of metal lines in the first metal line group of the 2D metal line pattern (e.g., the first, third, fifth and seventh columns of metal lines from the left as exemplarily shown in FIG. 1), and the widths of the mandrels 42 are related to line widths of metal lines in the second metal line group of the 2D metal line pattern (e.g., the second, fourth, and sixth columns of metal lines from the left as exemplarily shown in FIG. 1). Although some the mandrel recesses 41 appear to have the same widths and the mandrels 42 appear to have the same widths in the illustrative embodiment, this disclosure is not limited in this respect. In other embodiments, the widths of the mandrel recesses 41 may be different from each other, and the widths of the mandrels 42 may be different from each other as well.

Referring to FIG. 2 and the example illustrated in FIGS. 5A and 5B, the method 200 proceeds to step S03, where a spacer layer 50 is conformally deposited over the mandrel layer 40 and in the mandrel recesses 41. Specifically, the spacer layer 50 is deposited onto top and sidewalls of the mandrels 42 and top surfaces of the second thin film layer 35 exposed through the mandrel recesses 41. FIG. 5B is a top view of a structure at this stage, and FIG. 5A depicts a sectional view taken along line A5-A5 in FIG. 5B. The spacer layer 50 includes one or more elements of, for example but not limited to, Si, O, C. N, H, W, Ru, Mo, Ti, Ta, Nb, Sn, Al, etc. In some embodiments, the mandrel layer 40 may include, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., MOₓ, MOₓN_{y}, MOₓC_{y}, where M can be, for example, Ru, W, Ta, Ti, Al, or other suitable metal elements), other suitable materials, or any combination thereof. The spacer layer 50 is formed using, for example but not limited to, ALD, CVD, a blanket deposition process, other suitable processes, or any combination thereof. In accordance with some embodiments, the material used in the spacer layer 50 is different from the material used in the mandrel layer 40, so that the spacer layer 50 would not be removed during the subsequent etching of the mandrels 42. A thickness of the spacer layer 50 is related to the line widths of the metal lines in the first metal line group and is further related to spacing distances between a meal line in the first metal line group and an adjacent metal line in the second metal line group, and thus may be determined based on requirements of metal line patterning. In accordance with some embodiments, the thickness of the spacer layer 50 may range from about 10 angstroms to about 300 angstroms. It is noted that by defining the widths of the mandrel recesses 41, the widths of the mandrels 42 and the thickness of the spacer layer 50, the on-rule line 11 of the metal lines as exemplarily shown in FIG. 1 may be realized to have a uniform line width that equals the minimum line width.

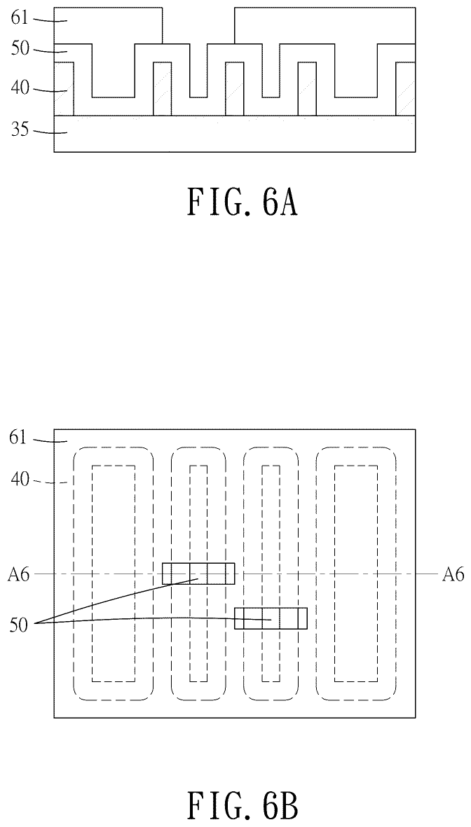

Referring to FIG. 2 and the example illustrated in FIGS. 6A and 6B, the method 200 proceeds to step S04, where a first patterning layer 61 is formed over the spacer layer 50. FIG. 6B is a top view of a structure at this stage, and FIG. 6A depicts a sectional view taken along line A6-A6 in FIG. 6B. The first patterning layer 61 is of a single-layer structure or a multi-layer structure. The first patterning layer 61 is formed, through a photolithography process, with at least one opening (e.g., two openings are shown in the example of FIG. 6B) that corresponds to the location of at least one cut position for a metal line in the first metal line group (e.g., two cut positions for the metal lines in the third and fifth columns from the left of the 2D metal line pattern of FIG. 1), and that exposes a part of the spacer layer 50 in at least one of the mandrel recesses 41. In some embodiments, the first patterning layer 61 includes, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The first patterning layer 61 may be treated with exposure and developing processes to form the openings therein.

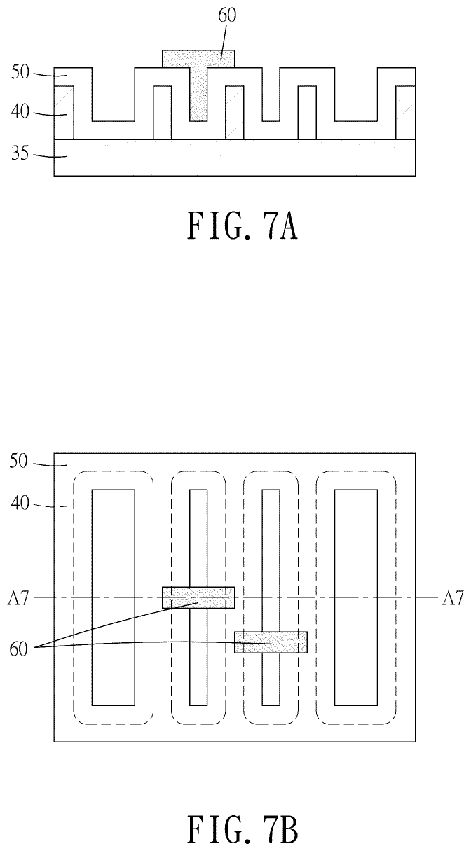

Referring to FIG. 2 and the example illustrated in FIGS. 7A and 7B, the method 200 proceeds to step S05, where a layer of a reverse material is formed over the first patterning layer 61 (see FIG. 6A) and within the at least one opening of the first patterning layer 61 to cover the at least one part of the spacer layer 50 exposed from the at least one opening, and an etching process is subsequently performed to remove the first patterning layer 61 and to etch back the reverse material so that a residue of the reverse material forms a first cut layer 60 for the at least one metal line in the first metal line group. FIG. 7B is a top view of a structure at this stage, and FIG. 7A depicts a sectional view taken along line A7-A7 in FIG. 7B. The first cut layer 60 is disposed on the spacer layer 50 at location(s) in one(s) of the mandrel recesses. In the example of FIG. 7B, the first cut layers 60 has two cut portions that are respectively formed for the metals lines in the third and fifth columns from the left of the 2D metal line pattern of FIG. 1. The reverse material includes one or more elements of, for example but not limited to, Si, O, C, N. H. W. Ru, Mo, Ti, Ta, Nb, Sn, Al, etc. In some embodiments, the reverse material may include, for example but not limited to, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., MOₓ, MOₓN_{y}, MOₓC_{y}, where M can be, for example, Ru, W, Ta, Ti, Al, or other suitable metal elements), other suitable materials, or any combination thereof. The layer of the reverse material is formed using, for example but not limited to, ALD, CVD, PVD. other suitable processes, or any combination thereof. The etching process used to remove the first patterning layer and to etch back the reverse material is an isotropic etching process. In accordance with some embodiments, the reverse material has an etching selectivity different from that of the material used in the spacer layer 50, so that the spacer layer 50 would not be removed during the etching process of the reverse material.

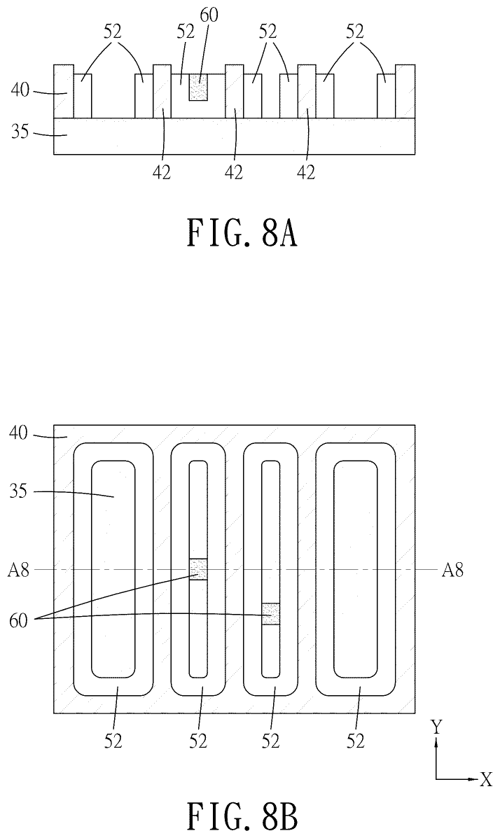

Referring to FIG. 2 and the example illustrated in FIGS. 8A and 8B, the method 200 proceeds to step S06, where the spacer layer 50 (see FIG. 7A) is etched anisotropically to form a first opening pattern using, for example but not limited to, wet etching, dry etching, other suitable techniques, or any combination thereof. The spacer layer 50 is etched anisotropically to expose a top surface of the mandrel layer 40 and to form spacer recesses (or called openings) in the spacer layer 50 and respectively in the mandrel recesses 41 (see FIG. 4A) by removing portions of the spacer layer 50 that are over the mandrels 42 and portions of the spacer layer 50 that are disposed at bottoms of the mandrel recesses 41 and not covered by the first cut layer 60 (see FIGS. 7A and 7B). FIG. 8B is a top view of a structure at this stage, and FIG. 8A depicts a sectional view taken along line A8-A8 in FIG. 8B. The spacer recesses extend in the Y-axis direction and expose the second thin film layer 35 of the masking layer, and at least two of the spacer recesses are aligned in the Y-axis direction and are spaced apart from each other in the Y-axis direction by the first cut layer 60 (e.g., the second and third columns of spacer recesses from the left of FIG. 8B are respectively cut by the two cut portions of the first cut layer 60 to each form two spacer recesses). The spacer recesses cooperate to form the first opening pattern. It is noted that the cut layer 60 may be etched back during the etching of the spacer layer 50 even though the etching selectivity of the reverse material of the first cut layer 60 is different from that of the material used in the spacer layer 50. Because the etching of the spacer layer 50 is anisotropic, portions of the spacer layer 50 that are formed on sidewalls of the mandrel layer 50 bordering the mandrel recesses 41 (namely, the sidewalls of the mandrels 42) remain. The remaining portions of the spacer layer 50 form a plurality of spacers 52 respectively in the mandrel recesses 41. Each of the spacers 52 is connected to the sidewall of the corresponding one of the mandrel recesses 41 and has the corresponding spacer recess formed therein. The spacer recesses thus formed correspond to the metal lines in the first metal line group of the 2D metal line pattern (i.e., the first, third, fifth and seventh columns of metal lines from the left as exemplarily shown in FIG. 1). Each of the spacer recesses is formed to have a respective width in the X-axis direction in order to form a corresponding metal line that has a corresponding line width.

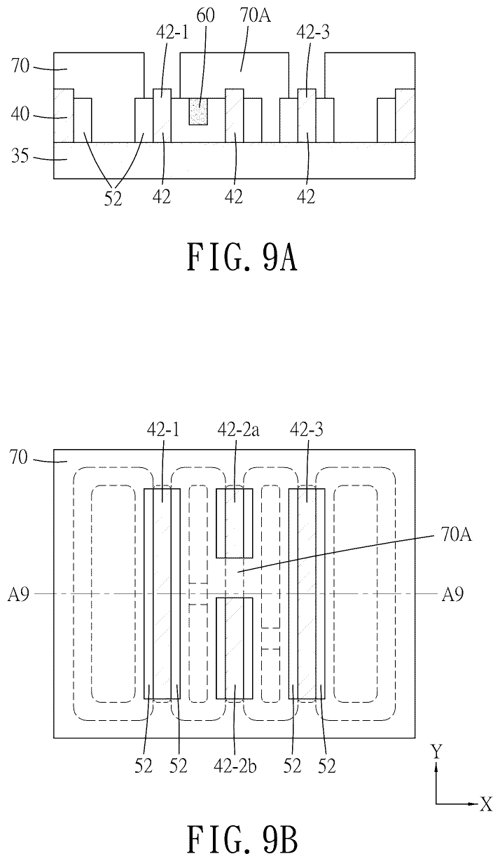

Referring to FIG. 2 and the example illustrated in FIGS. 9A and 9B, the method 200 proceeds to step S07, where a second patterning layer 70 is formed over the mandrel layer 40, the spacers 52 and the first cut layer 60. FIG. 9B is a top view of a structure at this stage, and FIG. 9A depicts a sectional view taken along line A9-A9 in FIG. 9B. The second patterning layer 70 covers each of the spacer recesses (namely, the spacer recesses are filled with the second patterning layer 70) and is formed, through a photolithography process, with multiple openings that correspond to a second opening pattern and that expose portions of the mandrels 42 of the mandrel layer 40. In the illustrative embodiment, the second patterning layer 70 includes first to fourth openings that respectively expose four portions 42-1, 42-2a, 42-2b, 42-3 of the mandrels 42 of the mandrel layer 40, which respectively correspond in position to the metal lines of the second metal line group in FIG. 1. A portion 70A of the second patterning layer 70 covers and crosses a middle part of one of the mandrels 42 (referred to as “the specific mandrel 42” hereinafter), and separates the second opening and the third opening from each other in the Y-axis direction by a distance, which specifies a line-end distance for the metal lines in the fourth column from the left as exemplarily shown in FIG. 1. In the illustrative embodiment, since the openings of the second patterning layer 70 are formed in positions corresponding to where the metal lines of the second metal line group are to be formed instead of where no metal line of the second metal line group is to be formed, use of the second patterning layer 70 thus configured facilitates subsequent formation of two mandrel openings that are aligned in the Y-axis direction in the specific mandrel 42. The second patterning layer 70 is of a single-layer structure or a multi-layer structure. In some embodiments, the second patterning layer 70 includes, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The second patterning layer 70 may be treated with exposure and developing processes to form the openings therein.

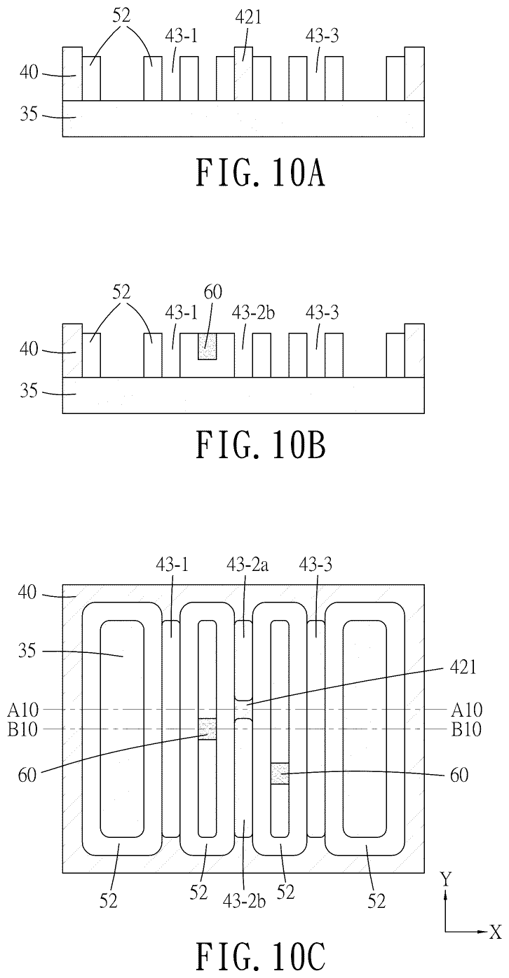

Referring to FIG. 2 and the example illustrated in FIGS. 10A, 10B and 10C. the method 200 proceeds to step S08, where the exposed portions of the mandrels 42-1. 42-2a, 42-2b, 42-3 of the mandrel layer 40 (see FIG. 9B) are etched with the second patterning layer 70 serving as a mask to form the second opening pattern in the mandrel layer 40. FIG. 10C is a top view of a structure at this stage, FIG. 10A depicts a sectional view taken along line A10-A10 in FIG. 10C, and FIG. 10B depicts a sectional view taken along line B10-B10 in FIG. 10C. The etching of the mandrels 42 may be performed using, for example, wet etching, dry etching, other suitable techniques, or any combination thereof. In the illustrative embodiment, the second opening pattern in the mandrel layer 40 includes multiple mandrel openings 43-1, 43-2a, 43-2b, 43-3 that expose the second thin film layer 35 and that are formed by etching the exposed portions of the mandrels 42-1, 42-2a, 42-2b, 42-3. In correspondence to the second opening and the third opening of the second patterning layer 70, the mandrel openings 43-2a, 43-2b in the specific mandrel 42 extend in the Y-axis direction, are aligned in the Y-axis direction, and are spaced apart from each other in the Y-axis direction by a line-end distance that is related to the distance specified by the portion 70A of the second patterning layer 70. In other words, a portion of the specific mandrel 42 in the mandrel layer 40 covered by the portion 70A of the second patterning layer 70 forms a second cut layer 421 that separates the mandrel openings 43-2a, 43-2b. In the illustrative embodiment, each of the mandrel openings 43-1, 43-2a, 43-2b, 43-3 in the mandrel layer 40 has a respective uniform width in the X-axis direction, but this disclosure is not limited in this respect.

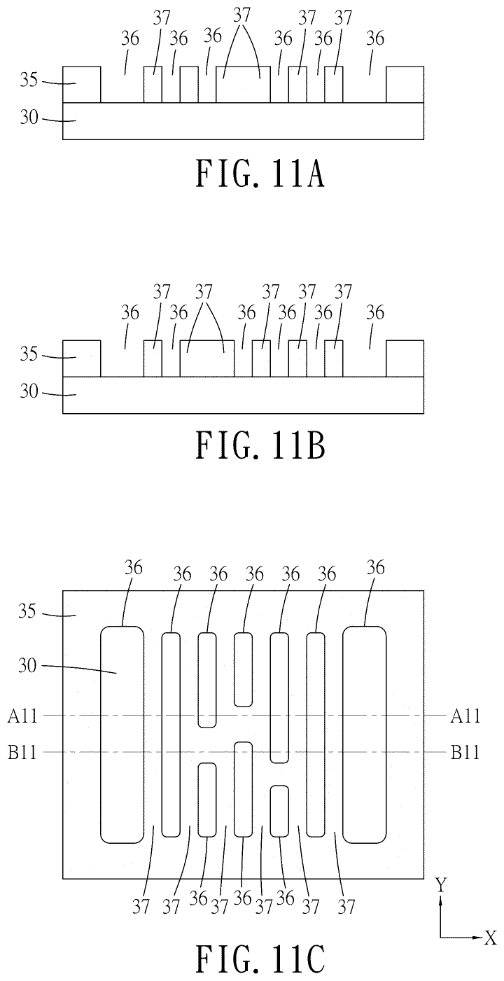

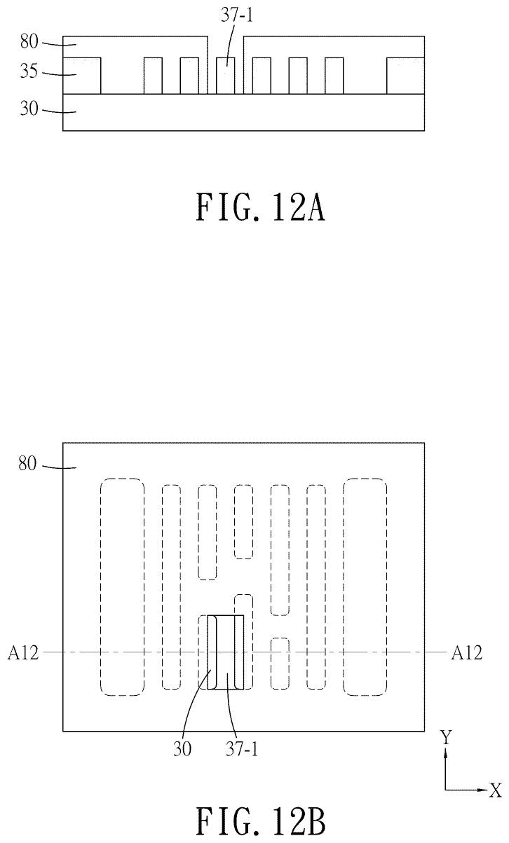

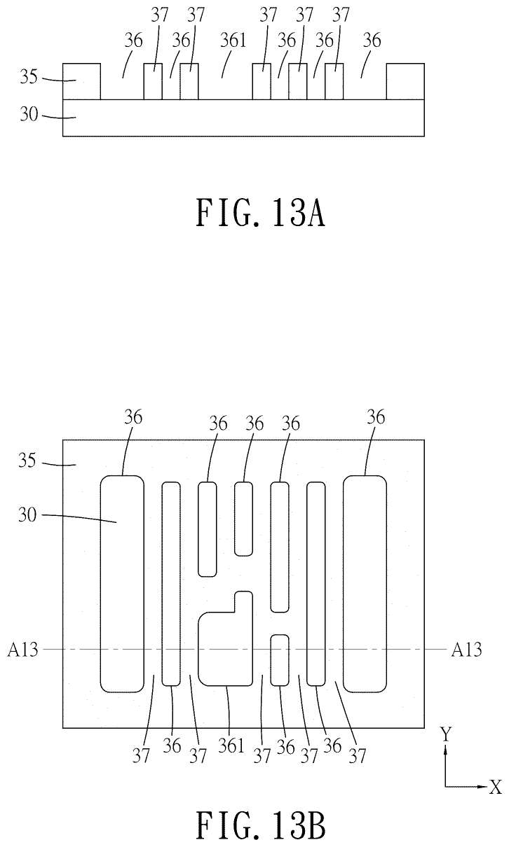

Referring to FIG. 2 and the example illustrated in FIGS. 11A, 11B and 11C, the method 200 proceeds to step S09, where the second thin film layer 35, which is a hard mask layer, is etched with the mandrel layer 40 (including the second cut layer 421), the spacers 52 and the first cut layer 60 collectively serving as a mask, so as to form a plurality of mask openings 36 in the second thin film layer 35 with the mask openings 36 being arranged in a pattern that is a combination of the first opening pattern and the second opening pattern and exposing the first thin film layer 30. FIG. 11C is a top view of a structure at this stage, FIG. 11A depicts a sectional view taken along line A11-A11 in FIG. 11C, and FIG. 11B depicts a sectional view taken along line B11-B11 in FIG. 11C. It is noted that FIG. 11A and FIG. 11B omit the layers 10, 15, 20 and 25 for the sake of clarity, and so do FIGS. 12A, 12B, 13A and 13B. The mask openings 36 extend in the Y-axis direction, are spaced apart from each other, some in the Y-axis direction and some in the X-axis direction, and form a plurality of spacing ridges 37 in the second thin film layer 35, where the spacing ridges 37 are arranged and spaced apart from each other in the X-axis direction and extend in the Y-axis direction. Each of the spacing ridges 37 is a portion of the second thin film layer 35 that is disposed between adjacent two of the mask openings 36. In the illustrative embodiment, the third to fifth columns of the mask openings 36 from the left each have two mask openings 36 that are separated by a cut ridge, wherein the cut ridges that separate these mask openings 36 are portions of the second thin film layer 35 that correspond in position to the first cut layer 60 and the second cut layer 421. The etching of the second thin film layer 35 may be performed using, for example, wet etching, dry etching, other suitable techniques, or any combination thereof. In step S09, the first opening pattern and the second opening pattern are transferred to the second thin film layer 35. The mandrel layer 40, the spacers 52 and the first cut layer 60 may be removed during or after the etching of the second thin film layer 35, and this disclosure is not limited in this respect. In accordance with some embodiments, the mandrel layer 40, the spacers 52 and the first cut layer 60 may be maintained after the etching of the second thin film layer 35.

Referring to FIG. 2 and the example illustrated in FIGS. 12A and 12B, the method 200 proceeds to step S10, where a third patterning layer 80 is formed over the second thin film layer 35 and the first thin film layer 30 exposed from the mask openings 36 (see FIGS. 11A and 11B) in the second thin film layer 35. FIG. 12B is a top view of a structure at this stage, and FIG. 12A depicts a sectional view taken along line A12-A12 in FIG. 12B. The third patterning layer 80 covers the mask openings 36 (namely, the mask openings 36 are filled with the third patterning layer 80) and is formed, through a photolithography process, with at least one opening that exposes a portion 37-1 of at least one of the spacing ridges 37 of the second thin film layer 35. The exposed portion 37-1 of the at least one spacing ridge 37 separates two adjacent mask openings 36 that are arranged in the X-axis direction and that have different lengths. In the illustrative embodiment, the third patterning layer 80 has one opening that exposes one portion 37-1 (hereinafter referred to as “the exposed portion 37-1”) of one of the spacing ridges 37 of the second thin film layer 35, which corresponds in position to a part of the irregular-width line 12 of the 2D metal line pattern as exemplarily shown in FIG. 1. In the illustrative embodiment, since the opening of the third patterning layer 80 is formed in the position corresponding to a separation between a metal line of the first metal line group and an adjacent metal line of the second metal line group, use of the third patterning layer 80 thus configured facilitates subsequent formation of an enlarged mask opening in the second thin film layer 35 that includes the two adjacent mask openings 36. The third patterning layer 80 is of a single-layer structure or a multi-layer structure. In some embodiments, the third patterning layer 80 includes, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The third patterning layer 80 may be treated with exposure and developing processes to form the opening(s) therein. It is noted that each of the at least one opening of the third patterning layer 80 is not limited to exposing a portion of only one of the spacing ridges 37 of the second thin film layer 35. In some embodiments, one opening of the third patterning layer 80 may expose portions of two or more of the spacing ridges 37.

Referring to FIG. 2 and the example illustrated in FIGS. 13A and 13B, the method 200 proceeds to step S11, where the exposed portion 37-1 of the at least one spacing ridge 37 of the second thin film layer 35 (see FIGS. 12A, 12B) is etched with the third patterning layer 80 serving as a mask to form the enlarged mask opening 361 in the second thin film layer 35, so that the mask openings 36 and the enlarged mask opening 361 are arranged in a third opening pattern. FIG. 13B is a top view of a structure at this stage, and FIG. 13A depicts a sectional view taken along line A13-A13 in FIG. 13B. The etching of the exposed portion 37-1 may be performed using, for example, wet etching, dry etching, other suitable techniques, or any combination thereof. In the illustrative embodiment, the exposed portion 37-1 that originally separates two adjacent mask openings 36 in the second thin film layer 35 from each other is removed, so that the two adjacent mask openings 36 are connected to form the enlarged mask opening 361 in the second thin film layer 35. It is noted that since the two adjacent mask openings 36 originally formed in step S09 have different lengths in the Y-axis direction, the enlarged mask opening 361 formed from the two adjacent mask openings 36 thus has a non-uniform width in the X-axis direction. That is to say, one segment of the enlarged mask opening 361 that is formed from a single one of the two adjacent mask openings 36 has a width smaller than a width of the remaining segment of the enlarged mask opening 361 that is formed from the two adjacent mask openings 36 together. In a scenario where the opening of the third patterning layer 80 may expose portions of two or more of the spacing ridges 37, the enlarged mask opening 361 formed by etching the exposed portions of the two or more of the spacing ridges 37 may cover three or more mask openings 36 that are originally formed in the second thin film layer 35 and separated by the two or more of the spacing ridges 37.

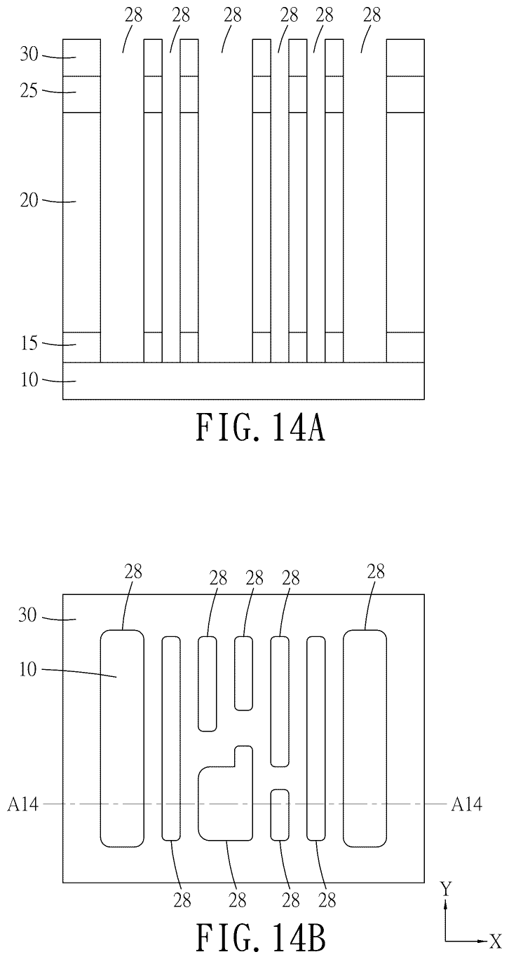

Referring to FIG. 2 and the example illustrated in FIGS. 14A and 14B, the method 200 proceeds to step S12, where the first thin film layer 30, the oxide layer 25, the dielectric layer 20 and the etch stop layer 15 are etched with the second thin film layer 35 serving as a mask, so as to form a plurality of openings 28 in the first thin film layer 30, the oxide layer 25, the dielectric layer 20 and the etch stop layer 15, with the openings 28 being arranged in accordance with the third opening pattern and exposing the semiconductor device layer 10. FIG. 14B is a top view of a structure at this stage, and FIG. 14A depicts a sectional view taken along line A14-A14 in FIG. 14B. In step S12, the third opening pattern is transferred to the first thin film layer 30, the oxide layer 25, the dielectric layer 20 and the etch stop layer 15. The second thin film layer 35 may be removed during or after the etching of the first thin film layer 30, the oxide layer 25, the dielectric layer 20 and the etch stop layer 15, and this disclosure is not limited in this respect. In accordance with some embodiments, the second thin film layer 35 may be maintained after the etching of the first thin film layer 30.

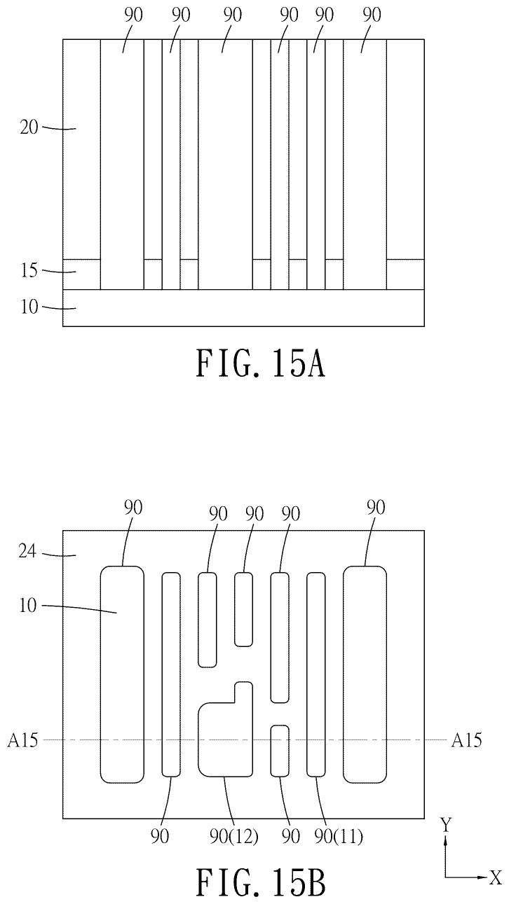

Referring to FIG. 2 and the example illustrated in FIGS. 15A and 15B, the method 200 proceeds to step S13, where a metallization process is performed to deposit a metal layer onto the first thin film layer 30 thus patterned and in the openings 28. followed by a planarization process to form a 2D metal line pattern that corresponds to the third opening pattern. FIG. 15B is a top view of a structure at this stage, and FIG. 15A depicts a sectional view taken along line A15-A15 in FIG. 15B. The 2D metal line pattern has a plurality of metal lines 90 that are arranged in accordance with the third opening pattern. In the illustrative embodiment, the metal lines 90 shown in FIG. 14B are the metal lines of the first metal line group and the metal lines of the second metal line group of FIG. 1, and include at least one on-rule line 11 that has the minimum line width and at least one irregular-width line 12 that has a non-uniform line width. In some embodiments, the metal layer includes, for example but not limited to, Cu, Ru, W, Ti, Al, Co, Mo, Ir, Rh, C, Nb, Zr, NiₓAl₁, CuₓAl_{y}, ScₓAl_{y}, RuₓAl_{y}, other suitable materials, or any combination thereof. The metal layer may be deposited using, for example, ALD, PVD, CVD, electrochemical plating (ECP), other suitable techniques, or any combination thereof. The planarization process may include, for example, dry etching, chemical-mechanical planarization (CMP), other suitable techniques, or any combination thereof. In some embodiments, the first thin film layer 30 and the oxide layer 25 are removed by the planarization process, but this disclosure is not limited in this respect.

In some embodiments, the metallization process further includes, prior to depositing the metal layer, conformally depositing a barrier layer onto the first thin film layer 30 thus patterned and in the openings 28, and conformally depositing a liner layer onto the barrier layer. In this way, after the planarization process, the metal lines formed from the metal layer are covered by liners formed from the liner layer and barriers formed from the barrier layer, and are thus separated from the dielectric layer 20 so that elements in a material of the metal lines may be blocked from migrating to surrounding structures (e.g., the dielectric layer 20 or the semiconductor device layer 10). In some embodiments, each of the barrier layer and liner layer includes, for example but not limited to, Ta, TaN, Ti, Co, Ru, Nb, W, Al, C, Zr, Mo, Ir, other suitable materials, or any combination thereof. In some embodiments, a thickness of a combination of the liner and the barrier ranges from about 5 angstroms to about 70 angstroms.

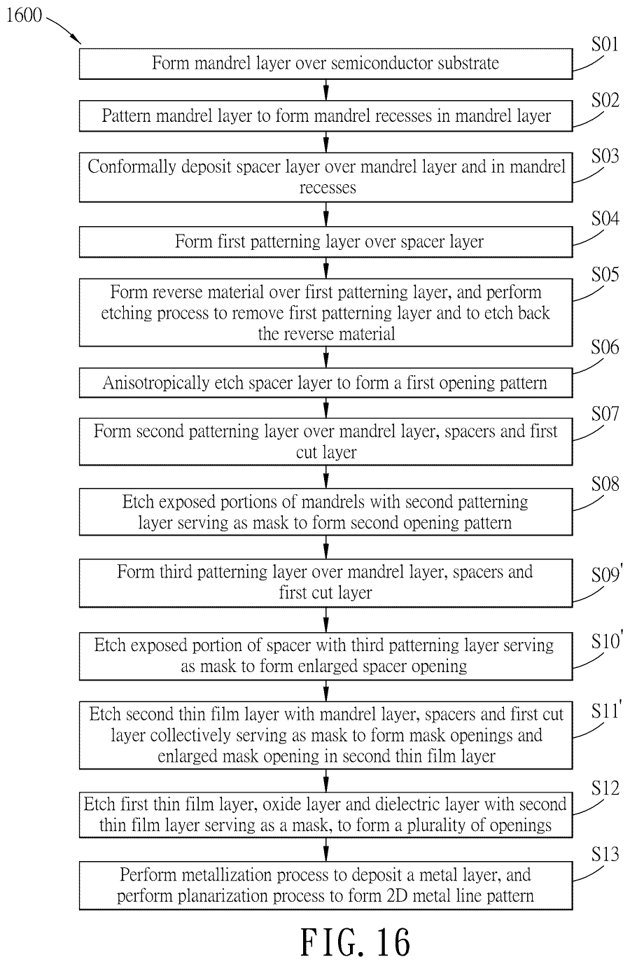

FIG. 16 is a flow diagram illustrating another method 1600 for 2D patterning utilized to fabricate the 2D metal line pattern as exemplarily shown in FIG. 1 in accordance with some embodiments. The method 1600 is similar to the method 200 of FIG. 2. and the differences reside in that in the method 200, step S10 of forming the third patterning layer 80 and step S11 of etching the exposed portion 37-1 of the at least one spacing ridge 37 are performed subsequent to step S09 of etching the hard mask layer (i.e., the second thin film layer 35), while in the method 1600, formation of the third patterning layer 80 and etching of an exposed portion of the spacers are performed prior to etching of the hard mask layer. In other words, the method 1600 includes steps S01-S08, S12 and S13 that are identical to those of the method 200, and steps S09′-S11′ that are different from S09-S11 of the method 200. FIGS. 17A, 17B, 18A, 18B, 13A and 13B illustrate schematic sectional views of intermediate stages in steps S09′-S11′ of the method 1600 in accordance with some embodiments.

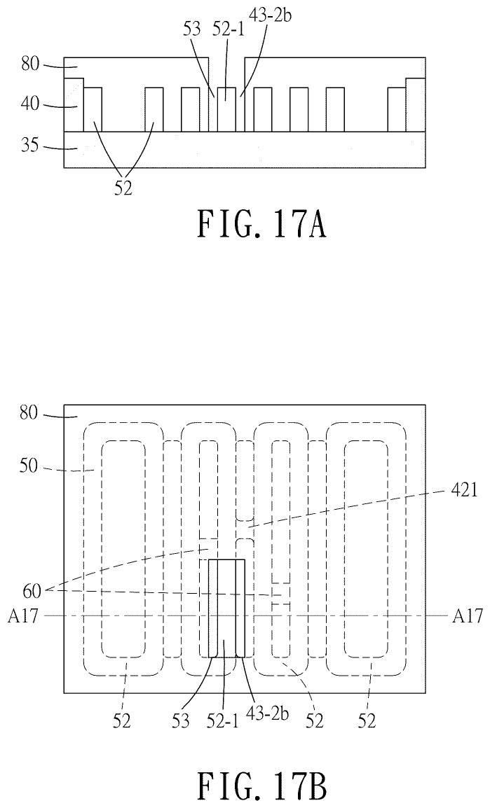

Referring to FIG. 16 and the example illustrated in FIGS. 17A and 17B, after S08 that has been explained referencing the accompanying FIGS. 10A-10C, the method 1600 proceeds to step S09′, where a third patterning layer 80 is formed over the mandrel layer 40 (including the second cut layer 421), the spacers 52 and the first cut layer 60. FIG. 17B is a top view of a structure at this stage, and FIG. 17A depicts a sectional view taken along line A17-A17 in FIG. 17B. The third patterning layer 80 covers the spacer recesses in the spacer layer 50 and the mandrel openings 43-1, 43-2a, 43-2b, 43-3 in the mandrel layer 40 (namely, the spacer recesses and the mandrel openings 43-1, 43-2a, 43-2b, 43-3 shown in FIG. 10C are filled with the third patterning layer 80), and is formed, through a photolithography process, with at least one opening that exposes a portion of at least one of the spacers 52. In the illustrative embodiment, the third patterning layer 80 includes one opening that exposes one portion 52-1 (hereinafter referred to as “the exposed portion 52-1”) of one of the spacers 52, which corresponds in position to a part of the irregular-width line 12 of the 2D metal line pattern as exemplarily shown in FIG. 1. In the illustrative embodiment, since the opening of the third patterning layer 80 is formed in the position corresponding to a separation between a metal line of the first metal line group and an adjacent metal line of the second metal line group, use of the third patterning layer 80 thus configured facilitates subsequent formation of an enlarged spacer opening in the spacer layer 50 that includes one of the spacer recesses (referred to as a to-be-merged recess 53 hereinafter) originally formed in step S06 and the adjacent mandrel opening 43-2b originally formed in step S08, which is one of the mandrel openings that is adjacent to the to-be-merged recess 53 and that has a length different from a length of the to-be-merged recess 53. The third patterning layer 80 is of a single-layer structure or a multi-layer structure. In some embodiments, the third patterning layer 80 includes, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The third patterning layer 80 may be treated with exposure and developing processes to form the opening(s) therein. It is noted that each of the at least one opening of the third patterning layer 80 is not limited to exposing a portion of only one of the spacers 52 of the spacer layer 50. In some embodiments, one opening of the third patterning layer 80 may expose portions of two or more of the spacers 52.

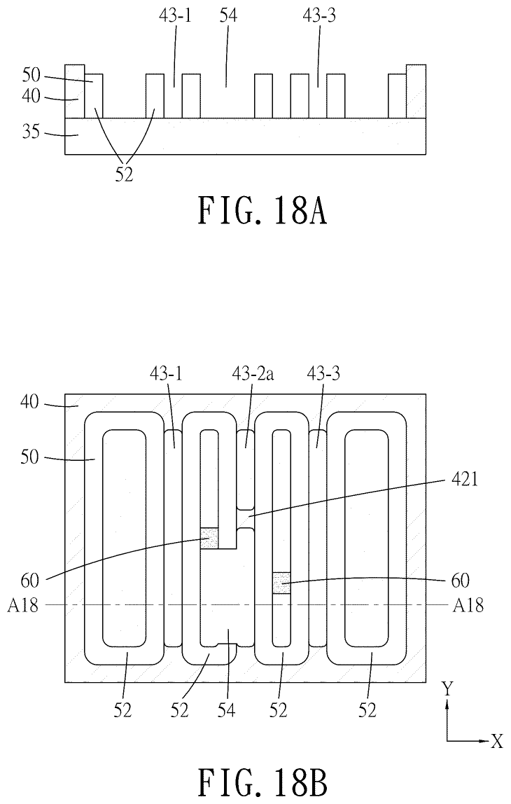

Referring to FIG. 16 and the example illustrated in FIGS. 18A and 18B, the method 1600 proceeds to step S10′, where the exposed portion 52-1 of the spacer 52 of the spacer layer 50 (see FIGS. 17A, 17B) is etched with the third patterning layer 80 serving as a mask to form the enlarged spacer opening 54 in the spacer layer 50, so that the spacer recesses, the mandrel openings 43-1, 43-2a, 43-3 and the enlarged spacer opening 54 are arranged in a third opening pattern. FIG. 18B is a top view of a structure at this stage, and FIG. 18A depicts a sectional view taken along line A18-A18 in FIG. 18B. The etching of the exposed portion 52-1 of the spacer 52 may be performed using, for example, wet etching, dry etching, other suitable techniques, or any combination thereof. In the illustrative embodiment, the exposed portion 52-1 of the spacer 52 that originally separates the to-be-merged recess 53 in the spacer layer 50 and the adjacent mandrel opening 43-2b in the mandrel layer 40 from each other is removed, so that the to-be-merged recess 53 and the adjacent mandrel opening 43-2b are connected to form the enlarged spacer opening 54 in the spacer layer 50. It is noted that since the to-be-merged recess 53 (see FIG. 17A) originally formed in step S06 and the adjacent mandrel opening 43-2b (see FIG. 17A) originally formed in step S08 have different lengths in the Y-axis direction, the enlarged spacer opening 54 formed from the to-be-merged recess 53 and the adjacent mandrel opening 43-2b thus has a non-uniform width in the X-axis direction. That is to say, one segment of the enlarged spacer opening 54 that is formed solely from the mandrel opening 43-2b has a width smaller than a width of the remaining segment of the enlarged spacer opening 54, which is formed from both the to-be-merged recess 53 and the adjacent mandrel opening 43-2b. In a scenario where the opening of the third patterning layer 80 may expose portions of two or more of the spacers 52, the enlarged spacer opening 54 formed by etching the exposed portions of the two or more of the spacers 52 may cover three or more recesses/openings from among the spacer recesses and the mandrel openings that are separated by the two or more of the spacers 52.

Referring to FIG. 16 and the example illustrated in FIGS. 13A and 13B, the method 1600 then proceeds to step S11′, where the second thin film layer 35, which is a hard mask layer, is etched with the mandrel layer 40 (including the second cut layer 421), the spacers 52 and the first cut layer 60 collectively serving as a mask (see FIGS. 18A, 18B), so as to form a plurality of mask openings 36 and an enlarged mask opening 361 in the second thin film layer 35 with the mask openings 36 and the enlarged mask opening 361 being arranged in a pattern substantially identical to the third opening pattern and exposing the first thin film layer 30. The mask openings 36 extend in the Y-axis direction, are spaced apart from each other, some in the X-axis direction and some in the Y-axis direction, and form a plurality of spacing ridges 37 in the second thin film layer 35, where the spacing ridges 37 are arranged and spaced apart from each other in the X-axis direction and extend in the Y-axis direction. Each of the spacing ridges 37 is a portion of the second thin film layer 35 that is disposed between adjacent two of the mask openings 36. In the illustrative embodiment, other portions of the second thin film layer 35 that correspond in position to and previously covered by the first cut layer 60 and the second cut layer 421 form cut ridges that each separate two of the mask openings 36 (e.g., the openings in the fifth column from the left) or separate one of the mask openings 36 (e.g., the opening in the third column from the left, or the opening in the fourth column from the left) from the enlarged mask opening 361. The enlarged mask opening 361 corresponds in position and in shape to the enlarged spacer opening 54 and thus has a non-uniform width in the X-axis direction. The etching of the second thin film layer 35 may be performed using, for example, wet etching, dry etching, other suitable techniques, or any combination thereof. In step S11′, the third opening pattern is transferred to the second thin film layer 35. The mandrel layer 40, the spacers 52 and the first cut layer 60 may be removed during or after the etching of the second thin film layer 35, and this disclosure is not limited in this respect. In accordance with some embodiments, the mandrel layer 40, the spacers 52 and the first cut layer 60 may remain after the etching of the second thin film layer 35.

After the second thin film layer 35 is etched to form the third opening pattern therein, the method 1600 proceeds to steps S12 and S13, which have been explained above in relation to the method 200 with reference to the accompanying FIGS. 14A, 14B, 15A and 15B, so as to form a 2D metal line pattern as exemplarily shown in FIG. 1. Detailed description related to steps S12 and S13 are omitted herein for the sake of brevity.

In an alternative embodiment, the dielectric layer 20 of the semiconductor substrate 1 may be replaced by a metal layer. Accordingly, in step S12, the first thin film layer 30, the oxide layer 25, the metal layer and the etch stop layer 15 are etched with the second thin film layer 35 serving as a mask, so as to form a plurality of openings 28 in the first thin film layer 30, the oxide layer 25, the metal layer and the etch stop layer 15 with the openings 28 being arranged in accordance with the third opening pattern and exposing the semiconductor device layer 10; and in step S13, a dielectric layer is deposited onto the first thin film layer 30 thus patterned and in the openings 28, followed by a planarization process to form a metal line pattern that is reverse to the third opening pattern, that is, the metal line pattern is formed by a dielectric pattern corresponding to the third opening pattern.

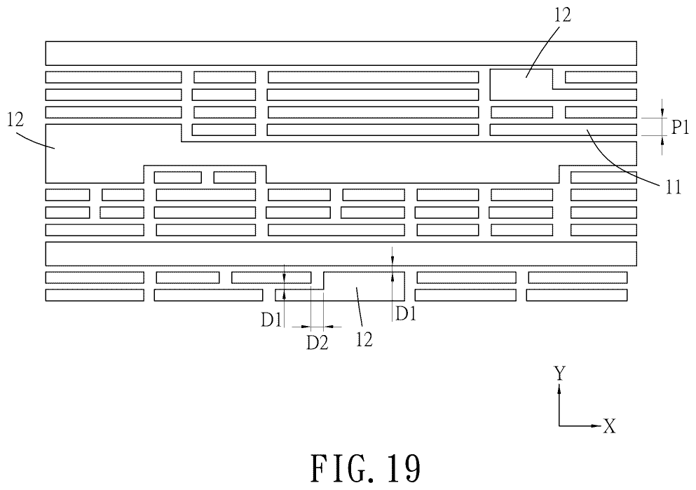

FIG. 19 is a schematic diagram illustrating another 2D metal line pattern formed on a semiconductor substrate (not shown) using the self-aligned 2D patterning technique of the method 200 or the method 1600 in accordance with some embodiments. The 2D metal line pattern includes metal lines that extend in the X-axis direction and that are spaced apart from each other, some in the X-axis direction and some in the Y-axis direction. The 2D metal line pattern is formed with a minimum pitch Pl of smaller than 70 nm, where the minimum pitch PI is a sum of a minimum line width and a minimum spacing distance. The metal lines of the 2D metal line pattern include at least one on-rule line 11 that has a uniform width equaling the minimum line width, and at least one irregular-width line 12 that has a non-uniform line width. The irregular-width line 12 may be looked at as an originally regular-width line where at least one segment of the line has its width growing in the Y-axis direction or a direction opposite to the Y-axis direction, or both. Moreover, the non-uniform line width of the irregular-width line 12 is no smaller than the minimum line width, and a minimum length of the irregular-width line 12 is greater than 20 nm. In addition, the irregular-width line 12 can be spaced apart from adjacent metal lines by spacing distances D1 in the Y-axis direction which is equal to the minimum spacing distance that can be achieved in a 1D metal line pattern, and the irregular-width line 12 can be spaced apart from an adjacent metal line by a cut distance D2 in the X-axis direction which is equal to a minimum cut distance that can be achieved in the 1D metal line pattern.

As described above, in a method for 2D patterning of the present disclosure, after the first opening pattern and the second opening pattern are formed using two sets of photolithography and etching processes, one more set of photolithography and etching process is performed to obtain the third opening pattern that includes an enlarged mask opening which combines two adjacent openings (or recesses) that are previously separated from each other and that have different lengths. In this way, the third opening pattern can be utilized to form a 2D metal line pattern that includes an irregular-width line which corresponds in shape to the enlarged mask opening and that has a non-uniform line width. This approach can be integrated in a stage of forming an interconnect layer that has a minimum pitch of smaller than 70 nm, which is achievable in a 1D metal line pattern (i.e., metal lines with uniform line widths) using a multiple patterning process. By adopting the method for 2D patterning of the present disclosure, there is no need to reserve an area specific for forming the irregular-width line therein, so the irregular- width line can be spaced apart from adjacent metal lines by a minimum spacing distance (in the Y-axis direction exemplarily shown in FIG. 19) and by a minimum cut distance (in the X-axis direction exemplarily shown in FIG. 19) that are achievable in the 1D metal line pattern. The non-uniform line width of the irregular-width line can have a minimum value that is equal to or greater than a minimum line width of an on-rule line. As a result, more design flexibility can be provided with restricted routing resources. Moreover, photolithography equipment for implementing the method for 2D patterning of the present disclosure is not limited, and may include an extreme ultraviolet lithography (EUV) tool, a deep ultraviolet (DUV) lithography tool, other suitable tools or any combination thereof. In addition, the method for 2D patterning of the present disclosure can be used in combination with a dual damascene process or a single damascene process to form the 2D line pattern, and can be implemented in one or both of a front-side interconnect layer and a back-side interconnect layer without imposing any restriction on processes for forming front-end of line (FEOL) devices. Accordingly, the method for 2D patterning of the present disclosure can maximize interconnect routing utility and release routing congestion, and also release the constraints on FEOL devices for more performance benefit.

In accordance with some embodiments of the present disclosure, a method of semiconductor fabrication includes forming a plurality of mandrel recesses in a mandrel layer over a hard mask layer, performing a first patterning process on a spacer layer that is deposited over the mandrel layer to form a first opening pattern, performing a second patterning process to etch portions of the mandrel layer to form a second opening pattern, performing a third patterning process to form a third opening pattern in the hard mask layer based on the first opening pattern and the second opening pattern, and forming, through the hard mask layer, metal lines that are in a semiconductor layer under the hard mask layer and that are arranged in a pattern which corresponds to the third opening pattern.

In accordance with some embodiments of the present disclosure, the performing a third patterning process includes patterning the hard mask layer to form a plurality of mask openings in the hard mask layer with the mask openings being arranged in a pattern that is the combination of the first opening pattern and the second opening pattern, and etching a portion of the hard mask layer that separates two adjacent mask openings which have different lengths among the mask openings to obtain an enlarged mask opening in the hard mask layer so that the mask openings and the enlarge mask opening are arranged to form the third opening pattern.

In accordance with some embodiments of the present disclosure, the performing a third patterning process includes etching a portion of the spacer layer that separates one of spacer recesses in the spacer layer and one of mandrel openings in the mandrel layer, which is adjacent to the one of the spacer recesses and which has a length different from a length of the one of the spacer recesses, so as to form an enlarged spacer opening, where the spacer recesses, the mandrel openings and the enlarged spacer opening cooperate to form the third opening pattern, and patterning the hard mask layer to form a plurality of mask openings and an enlarged mask opening in the hard mask layer with the mask openings and the enlarged mask opening being arranged in a pattern that is identical to the third opening pattern.

In accordance with some embodiments of the present disclosure, a method for two-dimensional (2D) patterning includes forming a plurality of mandrel recesses in a mandrel layer over a hard mask layer that is disposed over a dielectric layer, forming a plurality of spacer recesses of a spacer layer respectively in the mandrel recesses, where two of the spacer recesses extend in a direction, are aligned in the direction and are spaced apart from each other in the direction by a first cut layer, and the spacer recesses cooperate to form a first opening pattern, patterning the mandrel layer to form a second opening pattern in the mandrel layer, patterning the hard mask layer to form a plurality of mask openings in the hard mask layer with the mask openings being arranged in a pattern that is a combination of the first opening pattern and the second opening pattern, etching a portion of the hard mask layer that separates two adjacent mask openings which have different lengths among the mask openings to obtain an enlarged mask opening in the hard mask layer so that the mask openings and the enlarged mask opening are arranged in a third opening pattern, and forming, in the dielectric layer through the hard mask layer, metal lines that are arranged in a pattern which corresponds to the third opening pattern.

In accordance with some embodiments of the present disclosure, the forming a plurality of spacer recesses includes depositing the spacer layer over the mandrel layer and in the mandrel recesses, forming the first cut layer on the spacer layer in one of the mandrel recesses, and anisotropically etching the spacer layer to form the spacer recesses.

In accordance with some embodiments of the present disclosure, the forming the first cut layer includes forming a first patterning layer over the spacer layer, where the first patterning layer is formed with an opening that corresponds in location to a cut position for one of the metal lines and that exposes a part of the spacer layer in the one of the mandrel recesses, forming a layer of a reverse material over the first patterning layer and within the opening of the first patterning layer, and performing an etching process to remove the first patterning layer and to etch back the reverse material so that a residue of the reverse material forms the first cut layer.

In accordance with some embodiments of the present disclosure, the anisotropically etching the spacer layer exposes a top surface of the mandrel layer and forms the spacer recesses in the spacer layer and respectively in the mandrel recesses by removing portions of the spacer layer that are over the mandrel layer and portions of the spacer layer that are disposed at bottoms of the mandrel recesses and not covered by first cut layer.

In accordance with some embodiments of the present disclosure, the anisotropically etching the spacer layer maintains portions of the spacer layer that are formed on sidewalls of the mandrel layer bordering the mandrel recesses, where the portions of the spacer layer thus maintained form spacers each having a corresponding one of the spacer recesses formed therein.

In accordance with some embodiments of the present disclosure, patterning the mandrel layer includes forming a second patterning layer over the mandrel layer, the spacer layer and the first cut layer, where the second patterning layer covers each of the spacer recesses and is formed with multiple openings that correspond to the second opening pattern and that expose portions of the mandrel layer, and etching the portions of the mandrel layer with the second patterning layer serving as a mask to form the second opening pattern in the mandrel layer.

In accordance with some embodiments of the present disclosure, the second opening pattern in the mandrel layer includes multiple mandrel openings, where two of the mandrel openings extend in the direction, are aligned in the direction, and are spaced apart from each other in the direction by a second cut layer of the mandrel layer.

In accordance with some embodiments of the present disclosure, the method further includes, subsequent to patterning the hard mask layer, forming a third patterning layer over the hard mask layer, where the third patterning layer covers the mask openings and is formed with an opening that exposes the portion of the hard mask layer. In etching a portion of the hard mask layer, the portion of the hard mask layer is etched with the third patterning layer serving as a mask so that the two adjacent mask openings which have different lengths are connected to form the enlarged mask opening in the hard mask layer.

In accordance with some embodiments of the present disclosure, in etching a portion of the hard mask layer, one segment of the enlarged mask opening that is formed from a single one of the two adjacent mask openings has a width smaller than a width of the remaining segment of the enlarged mask opening that is formed from both the two adjacent mask openings.

In accordance with some embodiments of the present disclosure, a method for two-dimensional (2D) patterning includes forming a plurality of mandrel recesses in a mandrel layer over a hard mask layer that is disposed over a dielectric layer, forming a plurality of spacers respectively in the mandrel recesses, where the spacers are respectively connected to sidewalls of the mandrel layer bordering the mandrel recesses and have spacer recesses respectively formed therein, and two of the spacer recesses extend in a direction, are aligned in the direction and are spaced apart from each other in the direction by a first cut layer, patterning the mandrel layer to form a plurality of mandrel openings in the mandrel layer, where two of the mandrel openings extend in the direction, are aligned in the direction, and are spaced apart from each other in the direction by a second cut layer of the mandrel layer, etching a portion of one of the spacers that separates a to-be-merged recess of the spacer recesses and an adjacent mandrel opening, which is one of the mandrel openings adjacent to the to-be-merged recesses and which has a length different from a length of the to-be-merged recess, so as to form an enlarged spacer opening, patterning the hard mask layer with the mandrel layer, the spacers and the first cut layer collectively serving as a mask to form a plurality of mask openings and an enlarged mask opening in the hard mask layer, and forming, in the dielectric layer through the hard mask layer, metal lines that are arranged in a pattern in which the mask openings and the enlarged mask opening are arranged.

In accordance with some embodiments of the present disclosure, the forming a plurality of spacers includes depositing a spacer layer over the mandrel layer and in the mandrel recesses, forming the first cut layer on the spacer layer in one of the mandrel recesses, and anisotropically etching the spacer layer to form the spacers.

In accordance with some embodiments of the present disclosure, the forming the first cut layer includes forming a first patterning layer over the spacer layer, where the first patterning layer is formed with an opening that corresponds in location to a cut position for one of the metal lines and that exposes a part of the spacer layer in the one of the mandrel recesses, forming a layer of a reverse material over the first patterning layer and within the opening of the first patterning layer, and performing an etching process to remove the first patterning layer and to etch back the reverse material so that a residue of the reverse material forms the first cut layer.

In accordance with some embodiments of the present disclosure, the anisotropically etching the spacer layer exposes a top surface of the mandrel layer and forms the spacer recesses in the spacer layer and respectively in the mandrel recesses by removing portions of the spacer layer that are over the mandrel layer and portions of the spacer layer that are disposed at bottoms of the mandrel recesses and not covered by first cut layer.

In accordance with some embodiments of the present disclosure, the anisotropically etching the spacer layer maintains portions of the spacer layer that are formed on the sidewalls of the mandrel layer bordering the mandrel recesses, where the portions of the spacer layer thus maintained form the spacers.

In accordance with some embodiments of the present disclosure, the patterning the mandrel layer includes forming a second patterning layer over the mandrel layer, the spacers and the first cut layer, where the second patterning layer covers each of the spacer recesses and is formed with multiple openings that expose portions of the mandrel layer, and etching the portions of the mandrel layer with the second patterning layer serving as a mask to form the mandrel openings in the mandrel layer.

In accordance with some embodiments of the present disclosure, the method further includes, subsequent to patterning the mandrel layer, forming a third patterning layer over the mandrel layer, the spacers and the first cut layer, where the third patterning layer covers the spacer recesses and the mandrel openings, and is formed with at least one opening that exposes the portion of one of the spacers. In etching a portion of one of the spacers, the portion of the one of the spacers is etched with the third patterning layer serving as a mask so that the to-be-merged recess and the adjacent mandrel opening which have different lengths are connected to form the enlarged spacer opening.

In accordance with some embodiments of the present disclosure, in etching a portion of one of the spacers, one segment of the enlarged spacer opening that is formed from a single one of the to-be-merged recess and the adjacent mandrel opening has a width smaller than a width of the remaining segment of the enlarged spacer opening that is formed from both the to-be-merged recess and the adjacent mandrel opening.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of semiconductor fabrication, comprising:
forming a plurality of mandrel recesses in a mandrel layer over a hard mask layer;
performing a first patterning process on a spacer layer that is deposited over the mandrel layer to form a first opening pattern;
performing a second patterning process to etch portions of the mandrel layer to form a second opening pattern;
performing a third patterning process to form a third opening pattern in the hard mask layer based on the first opening pattern and the second opening pattern; and
forming, through the hard mask layer, metal lines that are in a semiconductor layer under the hard mask layer and that are arranged in a pattern which corresponds to the third opening pattern.

2. The method as claimed in claim 1, wherein performing a third patterning process includes:
patterning the hard mask layer to form a plurality of mask openings in the hard mask layer with the mask openings being arranged in a pattern that is the combination of the first opening pattern and the second opening pattern; and
etching a portion of the hard mask layer that separates two adjacent mask openings which have different lengths among the mask openings to obtain an enlarged mask opening in the hard mask layer so that the mask openings and the enlarge mask opening are arranged to form the third opening pattern.

3. The method as claimed in claim 1, wherein performing a third patterning process includes:
etching a portion of the spacer layer that separates one of spacer recesses in the spacer layer and one of mandrel openings in the mandrel layer, which is adjacent to the one of the spacer recesses and which has a length different from a length of the one of the spacer recesses, so as to form an enlarged spacer opening, where the spacer recesses, the mandrel openings and the enlarged spacer opening cooperate to form the third opening pattern; and
patterning the hard mask layer to form a plurality of mask openings and an enlarged mask opening in the hard mask layer with the mask openings and the enlarged mask opening being arranged in a pattern that is identical to the third opening pattern.

4. A method for two-dimensional (2D) patterning, comprising:
forming a plurality of mandrel recesses in a mandrel layer over a hard mask layer that is disposed over a dielectric layer;
forming a plurality of spacer recesses of a spacer layer respectively in the mandrel recesses, where two of the spacer recesses extend in a direction, are aligned in the direction and are spaced apart from each other in the direction by a first cut layer, and the spacer recesses cooperate to form a first opening pattern;
patterning the mandrel layer to form a second opening pattern in the mandrel layer;
patterning the hard mask layer to form a plurality of mask openings in the hard mask layer with the mask openings being arranged in a pattern that is a combination of the first opening pattern and the second opening pattern;
etching a portion of the hard mask layer that separates two adjacent mask openings which have different lengths among the mask openings to obtain an enlarged mask opening in the hard mask layer so that the mask openings and the enlarged mask opening are arranged in a third opening pattern; and
forming, in the dielectric layer through the hard mask layer, metal lines that are arranged in a pattern which corresponds to the third opening pattern.

5. The method as claimed in claim 4, wherein forming a plurality of spacer recesses includes:
depositing the spacer layer over the mandrel layer and in the mandrel recesses;
forming the first cut layer on the spacer layer in one of the mandrel recesses; and
anisotropically etching the spacer layer to form the spacer recesses.

6. The method as claimed in claim 5, wherein forming the first cut layer includes:
forming a first patterning layer over the spacer layer, where the first patterning layer is formed with an opening that corresponds in location to a cut position for one of the metal lines and that exposes a part of the spacer layer in the one of the mandrel recesses;
forming a layer of a reverse material over the first patterning layer and within the opening of the first patterning layer; and
performing an etching process to remove the first patterning layer and to etch back the reverse material so that a residue of the reverse material forms the first cut layer.

7. The method as claimed in claim 5, wherein anisotropically etching the spacer layer exposes a top surface of the mandrel layer and forms the spacer recesses in the spacer layer and respectively in the mandrel recesses by removing portions of the spacer layer that are over the mandrel layer and portions of the spacer layer that are disposed at bottoms of the mandrel recesses and not covered by first cut layer.

8. The method as claimed in claim 5, wherein anisotropically etching the spacer layer maintains portions of the spacer layer that are formed on sidewalls of the mandrel layer bordering the mandrel recesses, where the portions of the spacer layer thus maintained form spacers each having a corresponding one of the spacer recesses formed therein.

9. The method as claimed in claim 4, wherein patterning the mandrel layer includes:
forming a second patterning layer over the mandrel layer, the spacer layer and the first cut layer, where the second patterning layer covers each of the spacer recesses and is formed with multiple openings that correspond to the second opening pattern and that expose portions of the mandrel layer; and
etching the portions of the mandrel layer with the second patterning layer serving as a mask to form the second opening pattern in the mandrel layer.

10. The method as claimed in claim 9, wherein the second opening pattern in the mandrel layer includes multiple mandrel openings, where two of the mandrel openings extend in the direction, are aligned in the direction, and are spaced apart from each other in the direction by a second cut layer of the mandrel layer.

11. The method as claimed in claim 4, further comprising, subsequent to patterning the hard mask layer:
forming a third patterning layer over the hard mask layer, where the third patterning layer covers the mask openings and is formed with an opening that exposes the portion of the hard mask layer;
wherein in etching a portion of the hard mask layer, the portion of the hard mask layer is etched with the third patterning layer serving as a mask so that the two adjacent mask openings which have different lengths are connected to form the enlarged mask opening in the hard mask layer.

12. The method as claimed in claim 11, wherein in etching a portion of the hard mask layer, one segment of the enlarged mask opening that is formed from a single one of the two adjacent mask openings has a width smaller than a width of the remaining segment of the enlarged mask opening that is formed from both the two adjacent mask openings.

13. A method for two-dimensional (2D) patterning, comprising:
forming a plurality of mandrel recesses in a mandrel layer over a hard mask layer that is disposed over a dielectric layer;
forming a plurality of spacers respectively in the mandrel recesses, where the spacers are respectively connected to sidewalls of the mandrel layer bordering the mandrel recesses and have spacer recesses respectively formed therein, and two of the spacer recesses extend in a direction, are aligned in the direction and are spaced apart from each other in the direction by a first cut layer;
patterning the mandrel layer to form a plurality of mandrel openings in the mandrel layer, where two of the mandrel openings extend in the direction, are aligned in the direction, and are spaced apart from each other in the direction by a second cut layer of the mandrel layer;
etching a portion of one of the spacers that separates a to-be-merged recess of the spacer recesses and an adjacent mandrel opening, which is one of the mandrel openings adjacent to the to-be-merged recesses and which has a length different from a length of the to-be-merged recess, so as to form an enlarged spacer opening;
patterning the hard mask layer with the mandrel layer, the spacers and the first cut layer collectively serving as a mask to form a plurality of mask openings and an enlarged mask opening in the hard mask layer; and
forming, in the dielectric layer through the hard mask layer, metal lines that are arranged in a pattern in which the mask openings and the enlarged mask opening are arranged.

14. The method as claimed in claim 13, wherein forming a plurality of spacers includes:
depositing a spacer layer over the mandrel layer and in the mandrel recesses;
forming the first cut layer on the spacer layer in one of the mandrel recesses; and
anisotropically etching the spacer layer to form the spacers.

15. The method as claimed in claim 14, wherein forming the first cut layer includes:
forming a first patterning layer over the spacer layer, where the first patterning layer is formed with an opening that corresponds in location to a cut position for one of the metal lines and that exposes a part of the spacer layer in the one of the mandrel recesses;
forming a layer of a reverse material over the first patterning layer and within the opening of the first patterning layer; and
performing an etching process to remove the first patterning layer and to etch back the reverse material so that a residue of the reverse material forms the first cut layer.

16. The method as claimed in claim 14, wherein anisotropically etching the spacer layer exposes a top surface of the mandrel layer and forms the spacer recesses in the spacer layer and respectively in the mandrel recesses by removing portions of the spacer layer that are over the mandrel layer and portions of the spacer layer that are disposed at bottoms of the mandrel recesses and not covered by first cut layer.

17. The method as claimed in claim 14, wherein anisotropically etching the spacer layer maintains portions of the spacer layer that are formed on the sidewalls of the mandrel layer bordering the mandrel recesses, where the portions of the spacer layer thus maintained form the spacers.

18. The method as claimed in claim 13, wherein patterning the mandrel layer includes:
forming a second patterning layer over the mandrel layer, the spacers and the first cut layer, where the second patterning layer covers each of the spacer recesses and is formed with multiple openings that expose portions of the mandrel layer; and
etching the portions of the mandrel layer with the second patterning layer serving as a mask to form the mandrel openings in the mandrel layer.

19. The method as claimed in claim 13, further comprising, subsequent to patterning the mandrel layer:
forming a third patterning layer over the mandrel layer, the spacers and the first cut layer, where the third patterning layer covers the spacer recesses and the mandrel openings, and is formed with at least one opening that exposes the portion of one of the spacers;
wherein in etching a portion of one of the spacers, the portion of the one of the spacers is etched with the third patterning layer serving as a mask so that the to-be-merged recess and the adjacent mandrel opening which have different lengths are connected to form the enlarged spacer opening.

20. The method as claimed in claim 19, wherein in etching a portion of one of the spacers, one segment of the enlarged spacer opening that is formed from a single one of the to-be-merged recess and the adjacent mandrel opening has a width smaller than a width of the remaining segment of the enlarged spacer opening that is formed from both the to-be-merged recess and the adjacent mandrel opening.
